(19) United States
(12) Patent Application Publication
(10) Pub. No.: US 2009/0053870 A1
(43) Pub. Date: Feb. 26, 2009

(54) METHOD FOR PREPARING FLASH MEMORY STRUCTURES

(75) Inventors: CHUNG WE PAN, PINGTUNG COUNTY (TW); TZENG WEN TZENG, TAOYUAN COUNTY (TW); MING YU HO, TAICHUNG COUNTRY (TW); YEN YU HSU, HSINCHU COUNTY (TW); CHIH PING CHUNG, HSINCHU CITY (TW); CHING HUNG FU, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/031,653

(22) Filed: Feb. 14, 2008

(30) Foreign Application Priority Data
Aug. 22, 2007 (TW) 096131015

(51) Int. Cl. H01L 21/8239

(52) U.S. Cl. 438/287; 257/E21.645

(57) ABSTRACT

A method for preparing a flash memory structure comprises the steps of forming a plurality of dielectric blocks having block sidewalls on a substrate, forming a plurality of first spacers on the block sidewalls of the dielectric blocks, removing a portion of the substrate not covered by the dielectric blocks and the first spacers to form a plurality of trenches in the substrate, performing a deposition process to form an isolation dielectric layer filling the trenches, removing the dielectric blocks to expose spacer sidewalls of the first spacers, forming a plurality of second spacers on the spacer sidewalls of the first spacers, and removing a portion of the substrate not covered by the first spacers, the second spacers and the isolation dielectric layer to form a plurality of second trenches in the substrate.

### BACKGROUND OF THE INVENTION

(A) Field of the Invention

The present invention relates to a method for preparing a flash memory structure, and more particularly, to a method for preparing a flash memory structure including patterns having a width smaller than the critical dimension (CD) of the photolithographic process.

(B) Description of the Related Art

Owing to the advantages of lower power consumption, fast access and recording data even without a continuous power supply, flash memory has been widely applied to the data storage of digital products such as laptop computers, digital assistants, cell phones, digital cameras, digital recorders, and MP3 players. Typically, the flash memory device comprises a silicon-oxide-nitride-oxide-silicon (SONOS) structure, which is widely used in flash memory since it possesses the advantages of a thinner memory cell and a simpler fabrication process.

FIG. 1 illustrates a flash memory cell 10 having a SONOS structure according to the prior art. The flash memory cell 10 comprises a silicon substrate 12, two doped regions 14 and 16, a tunnel oxide layer 22, a silicon nitride layer 24, an oxide layer 26 and a polysilicon layer 28. Particularly, the SONOS structure consists of the silicon substrate 12, the tunnel oxide layer 22, the silicon nitride layer 24, the oxide layer 26 and the polysilicon layer 28. While charge-trapping sites in the silicon nitride layer 24 can capture electrons or holes penetrating the tunnel oxide 22, the oxide layer 26 serves to prevent electrons and holes from escaping from the silicon nitride layer 24 and entering into the polysilicon layer 28 during writing or erasing operations of the flash memory device.

When the polysilicon layer 28, serving as the gate electrode, is charged 14 2 to a positive potential, electrons in the silicon substrate 12 will be injected into the silicon nitride layer 24. Inversely, a portion of electrons in the silicon nitride layer 24 will be repulsed from the silicon substrate 12 to form holes in the silicon nitride layer 24 when the polysilicon layer 28 is charged to a negative potential. Electrons and holes trapped in the silicon nitride layer 24 change the threshold voltage (Vₜₕ) of the flash memory cell 10, and different threshold voltages represent different data bits stored by the flash memory device, i.e., “1” and “0”.

The occupied silicon surface of the flash memory structure 10 depends on the critical dimension of the photolithographic process, which is the smallest size the photolithographic process can fabricate. The conventional techniques try to shrink the critical dimension by optical proximity correction (OPC), off-axis illumination (OAI), phase-shifting mask (PSM) and double exposure so as to increase the storage density of the flash memory device.

### SUMMARY OF THE INVENTION

One aspect of the present invention provides a method for preparing a flash memory structure by using the spacer to shrink the opening of the etching mask so as to fabricate structural patterns having a width smaller than the critical dimension of the photolithographic process in order to increase the storage density of the flash memory device.

A method for preparing a flash memory structure according to this aspect of the present invention comprises the steps of forming a plurality of dielectric blocks having block sidewalls on a substrate, forming a plurality of first spacers on the block sidewalls of the dielectric blocks, removing a portion of the substrate not covered by the dielectric blocks and the first spacers to form a plurality of trenches in the substrate, performing a deposition process to form an isolation dielectric layer filling the trenches, removing the dielectric blocks to expose spacer sidewalls of the first spacers, forming a plurality of second spacers on the spacer sidewalls of the first spacers, and removing a portion of the substrate not covered by the first spacers, the second spacers and the isolation dielectric layer to form a plurality of second trenches in the substrate.

Another aspect of the present invention provides a method for preparing a flash memory structure comprising the steps of forming a plurality of dielectric blocks having block sidewalls on a substrate, forming a plurality of first spacers on the block sidewalls of the dielectric blocks, removing a portion of the substrate not covered by the dielectric blocks and the first spacers to form a plurality of first depressions in the substrate, performing a first implanting process to form a plurality of first doped regions in the substrate below the first depressions, performing a deposition process to form an isolation dielectric layer filling the first depressions, removing the dielectric blocks to expose spacer sidewalls of the first spacers, forming a plurality of second spacers on the spacer sidewalls of the first spacers, removing a portion of the substrate not covered by the first spacers, the second spacers and the isolation dielectric layer to form a plurality of second depressions in the substrate, and performing a second implanting process to form a plurality of second doped regions in the substrate below the second depressions.

The present application divides the shallow trench isolation structure (the memory cell structure is the same) into two groups, uses the etching mask including the spacer to pattern the two shallow trench isolation groups, and performs two etching processes to form the complete shallow trench isolation structure. In particular, the present application uses the spacers to shrink the opening formed by the photolithographic process so as to fabricate a shallow trench isolation structure having a width smaller than the critical dimension of the photolithographic process in order to increase the storage density of the flash memory device.

### BRIEF DESCRIPTION OF THE DRAWINGS

The objectives and advantages of the present invention will become apparent upon reading the following description and upon reference to the accompanying drawings in which:

FIG. 1 illustrates a flash memory cell with a SONOS structure according to the prior art;

FIG. 2 to FIG. 20 illustrates a method for preparing a flash memory structure according to one embodiment of the present invention; and

FIG. 21 to FIG. 23 illustrate a method for preparing a flash memory structure according to another embodiment of the present invention.

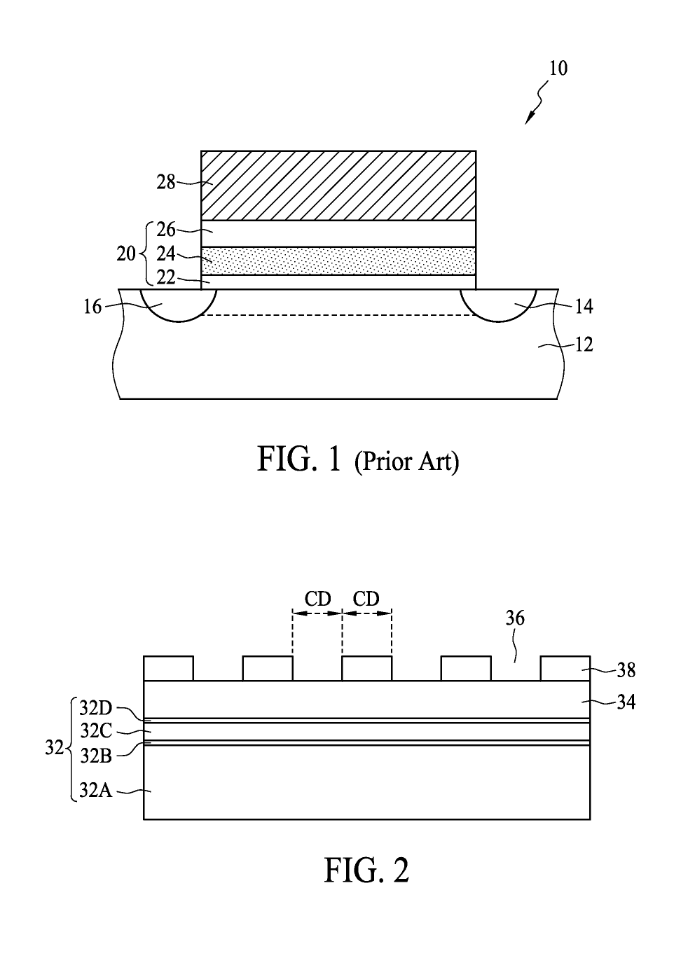

### DETAILED DESCRIPTION OF THE INVENTION

FIG. 2 to FIG. 20 illustrates a method for preparing a flash memory structure 30 according to one embodiment of the present invention, wherein FIG. 2 to FIG. 11 are cross-sectional views along a word line of the flash memory structure 30 and FIG. 12 to FIG. 20 are cross-sectional views along a bit line of the flash memory structure 30. First, a deposition process is performed to form a dielectric layer 34 on a substrate 32, and a photolithographic process is then performed to form a plurality of masks 38 on the dielectric layer 34, wherein the masks 38 are separated by a plurality of openings 36. Preferably, the dielectric layer 34 includes silicon oxide, and the masks 38 are made of photoresist material.

In particular, the openings 36 and the masks 38 have the same width, which is the critical dimension of the photolithographic process. The substrate 32 includes a silicon substrate 32A, a dielectric structure 32B, a polysilicon layer 32C and a silicon oxide layer 32D. The dielectric structure 32 can consist of three dielectric layers, silicon oxide-silicon nitride-silicon oxide, which combines with the silicon substrate 32A and the polysilicon layer 32C to form a silicon-oxide-nitride-oxide-silicon (SONOS) structure for the SONOS-type flash memory device.

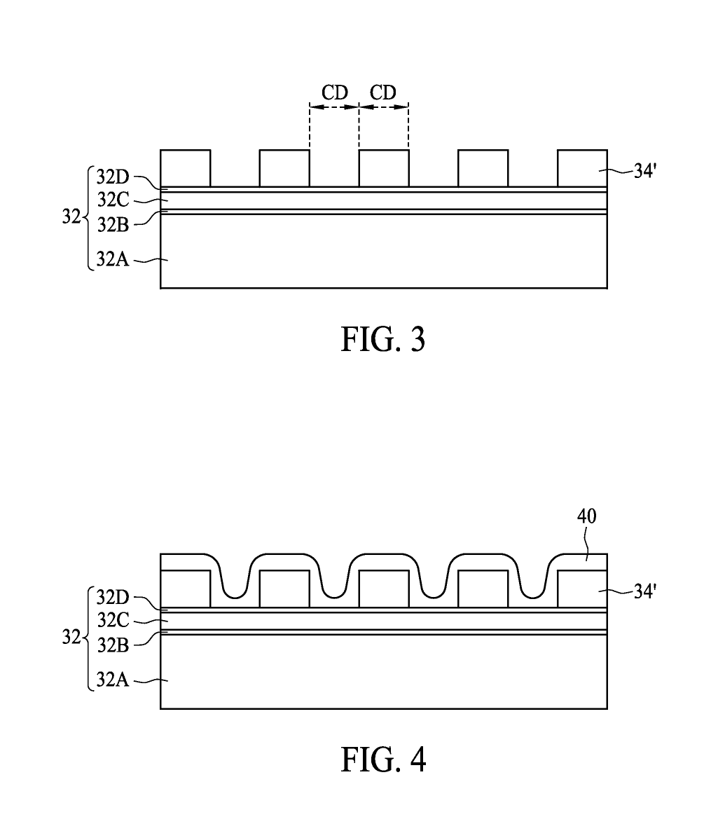

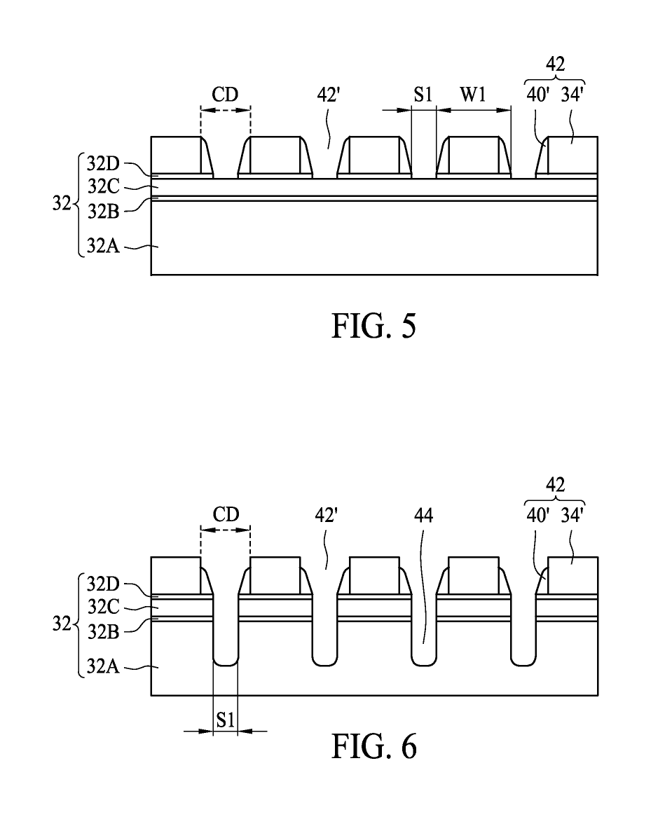

Referring to FIG. 3, an anisotropic dry etching process is performed to remove a portion of the dielectric layer 34 under the openings 36 down to the surface of the substrate 32, and the masks 38 are then completely removed to form a plurality of dielectric blocks 34′ on the substrate 32. The width of the dielectric blocks 34′ is equal to the width of the masks 38 and the spacing between the dielectric blocks 34′ is equal to the width of the openings 36, i.e., the width and the spacing of the dielectric blocks 34′ are both equal to the critical dimension of the photolithographic process. Subsequently, a deposition process is performed to form a dielectric layer 40 preferably made of silicon oxide covering the substrate 32 and the dielectric blocks 34′, as shown in FIG. 4. Referring to FIG. 5, an anisotropic dry etching process is performed to remove a portion of the dielectric layer 40 to form a plurality of spacers 40′ on the sidewall of the dielectric blocks 34′. The dielectric blocks 34′ and the spacers 40′ form an etching mask 42 having a plurality of openings 42′, and the width (W1) of the etching mask 42 between the openings 42′ is three times larger than width (S1) of the openings 42′, i.e., the width of the etching mask 42 is larger than the space. The anisotropic dry etching process also removes a portion of the silicon oxide layer 32D not covered by the etching mask 42. In particular, the spacers 40′ at the two sides of the dielectric blocks 34′ cause the width (S1) of the openings 42′ to be smaller than the width of the opening 36, which equals to the critical dimension of the photolithographic process.

Referring to FIG. 6, an anisotropic dry etching is performed to remove a portion of the substrate 32 not covered by the etching mask 42 to form a plurality of trenches 44 in the substrate 32. The anisotropic dry etching removes a portion of the substrate 32 under the openings 42′ down to the interior of the silicon substrate 32A such that the bottom of the trenches 44 is formed inside the silicon substrate 32A. The spacers 40′ at the two sides of the dielectric blocks 34′ cause the width (S1) of the openings 42′ is smaller than the critical dimension of the photolithographic process, and the width of the trenches 44 is equal to the width (S1) of the openings 42′. Consequently, the width of the trench 44 is smaller than the critical dimension of the photolithographic process.

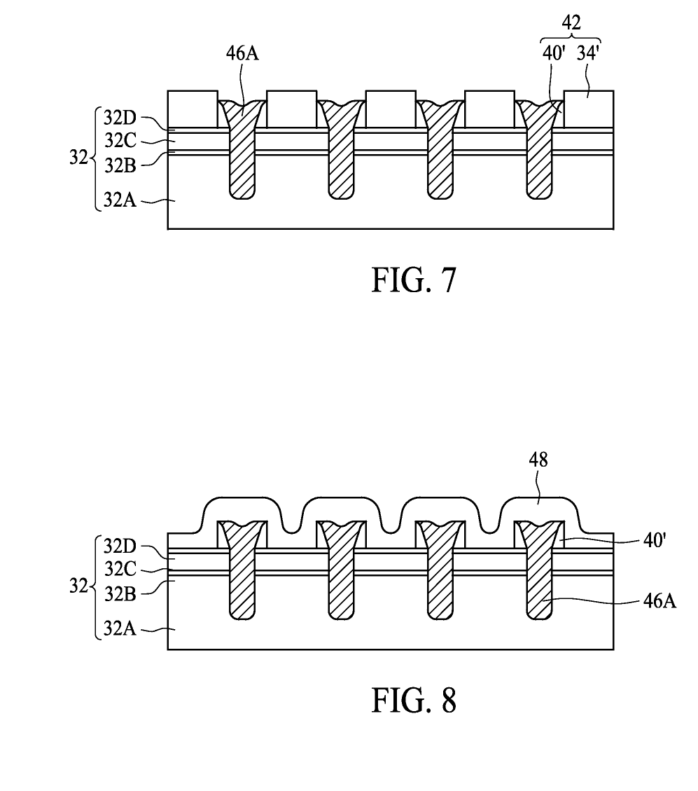

Referring to FIG. 7, a high-density plasma chemical vapor phase deposition (HDPCVD) process and an etching process are performed to form an isolation dielectric layer 46A filling the trenches 44. Subsequently, a wet etching process is performed to completely remove the dielectric blocks 34′ to expose the sidewalls of the spacers 40′, and a deposition process is then performed to form a dielectric layer 48 made of silicon oxide covering the substrate 32, the spacers 40′ and the isolation dielectric layer 46A, as shown in FIG. 8.

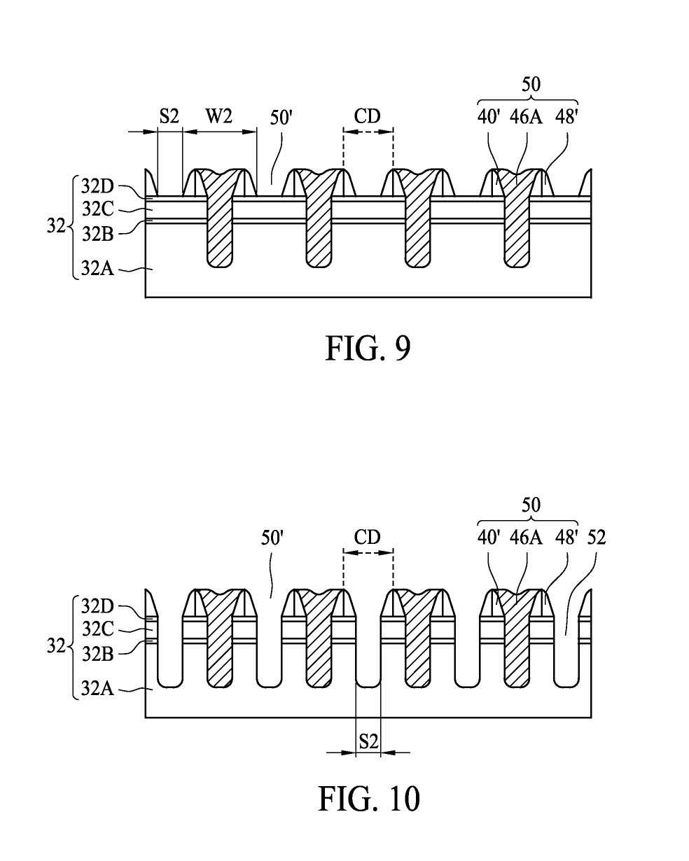

Referring to FIG. 9, an anisotropic dry etching process is performed to remove a portion of the dielectric layer 48 to form a plurality of spacers 48′ on the sidewalls of the spacers 40′. In particular, the spacers 40′, the spacers 48′ and the isolation dielectric layer 46A form an etching mask 50 having a plurality of openings 50′, and the width (W2) of the etching mask 50 between the openings 50′ is three times larger than the width (S2) of the openings 50′. The openings 50′ of the etching mask 50 is formed between the openings 42′ of the etching mask 42. Just as the spacers 40′ at the two sides of the dielectric blocks 34′ cause the width (S1) of the openings 42′ to be smaller than the critical dimension of the photolithographic process, the spacers 48′ also cause the width of the openings 50′ to be smaller than the critical dimension of the photolithographic process.

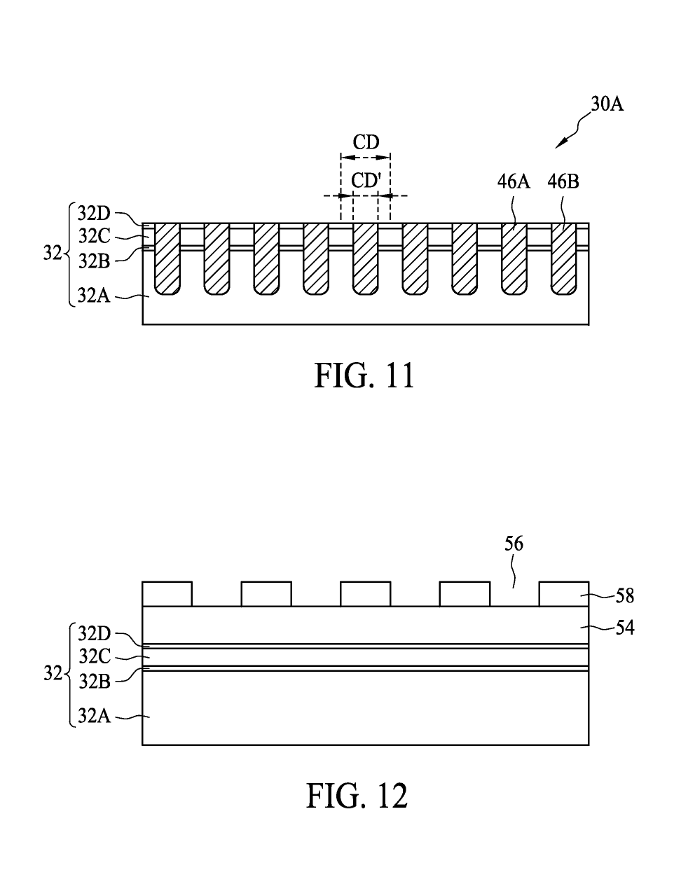

Referring to FIG. 10, an anisotropic dry etching process is performed to remove a portion of the substrate 32 not covered by the etching mask 50 to form a plurality of trenches 52 in the substrate 32. The anisotropic dry etching removes a portion of the substrate 32 under the openings 50′ down to the interior of the silicon substrate 32A such that the bottom of the trenches 52 is formed inside the silicon substrate 32A. Subsequently, a high-density plasma chemical vapor phase deposition process and an etching process are performed to form an isolation dielectric layer 46B filling the trenches 52, and a chemical-mechanical polishing process is then performed to remove a portion of the etching mask 50 on the silicon oxide layer 32D to complete a shallow trench isolation structure 30A, as shown in FIG. 11.

The isolation dielectric layer 46A in the trenches 44 and the isolation dielectric layer 46B in the trenches 52 form the shallow trench isolation structure 30A. In other words, the present application divides the shallow trench isolation structure 30A into two groups, uses the etching mask 42 including the spacers 40′ and the etching mask 50 including the spacers 48′ to pattern the two groups of trenches 44 and 52 respectively, and performs two etching processes to form the complete shallow trench isolation structure 30A. In particular, the present application uses the spacers 40′, 48′ to shrink the openings 42′, 50′ formed by the photolithographic process so as to fabricate the trenches 44, 52 having a width (CD′) smaller than the critical dimension (CD) of the photolithographic process.

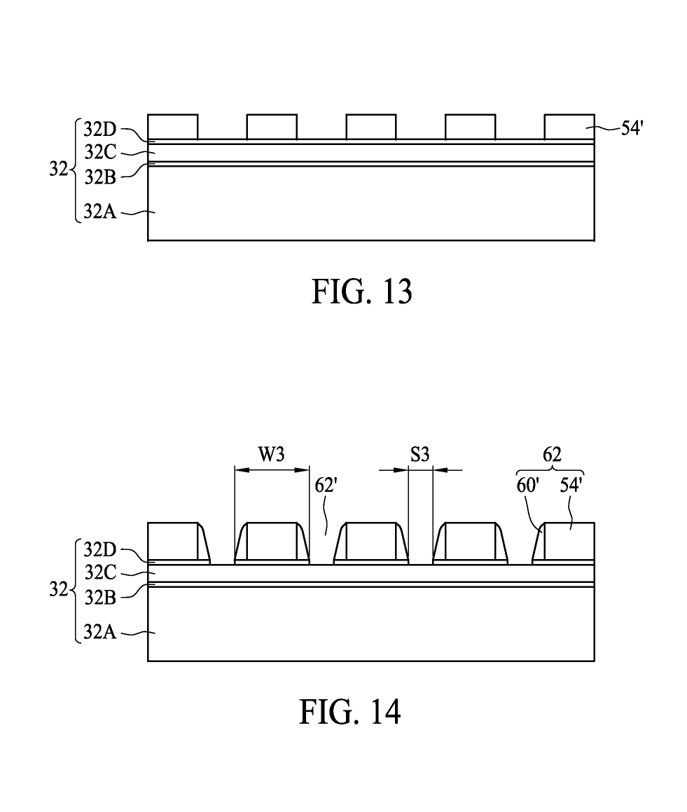

Referring to FIG. 12 to FIG. 19, these are cross-sectional views along the bit line perpendicular to the word line of the flash memory structure 30. A deposition process is performed to form a dielectric layer 54 on the substrate 32, and a photolithographic process is then performed to form a plurality of masks 58 on the dielectric layer 54, wherein the masks 58 are separated by openings 56. Subsequently, an anisotropic dry etching process is performed to remove a portion of the dielectric layer 54 under the openings 56 down to the surface of the substrate 32, and the masks 58 are completely removed to form a plurality of dielectric blocks 54′ on the substrate 32, as shown in FIG. 13. The width of the dielectric blocks 54′ are equal, and the dielectric blocks 54′ are formed on the substrate 32 in an equally spaced manner. Therefore, the width is equal to the spacing of the dielectric blocks 54′.

Referring to FIG. 14, a deposition process is performed to form a dielectric layer made of silicon oxide covering the substrate 32 and the dielectric blocks 54′, and an anisotropic dry etching process is then performed to remove a portion of the dielectric layer to form a plurality of spacers 60′ on the sidewalls of the dielectric blocks 54′. The dielectric blocks 54′ and the spacers 60′ form an etching mask 62 having a plurality of openings 62′, and the width (W3) of the etching mask 62 between the openings 62′ is three times larger than the width (S3) of the openings 62′, i.e., the width of the etching mask 62 is larger than the spacing of the etching mask 62. In addition, the anisotropic dry etching process also removes a portion of the silicon oxide layer 32D not covered by the etching mask 62.

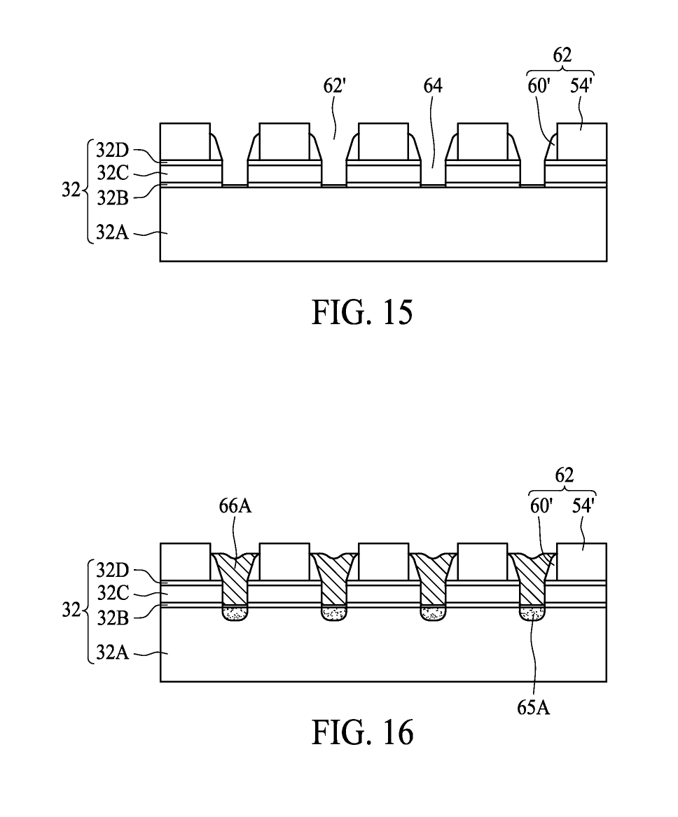

Referring to FIG. 15, an anisotropic dry etching process is performed to remove a portion of the substrate 32 not covered by the etching mask 62 to form a plurality of depressions 64 in the substrate 32. The anisotropic dry etching removes a portion of the substrate 32 under the openings 62′ down to the interior of the dielectric structure 32B such that the bottom of the depressions 64 is formed inside the dielectric structure 32B. Subsequently, an implanting process is performed to form a plurality of doped regions 65A in the silicon substrate 32A below the depressions 64, and a high-density plasma chemical vapor phase deposition process and an etching process are performed to form an isolation dielectric layer 66A filling the depressions 64.

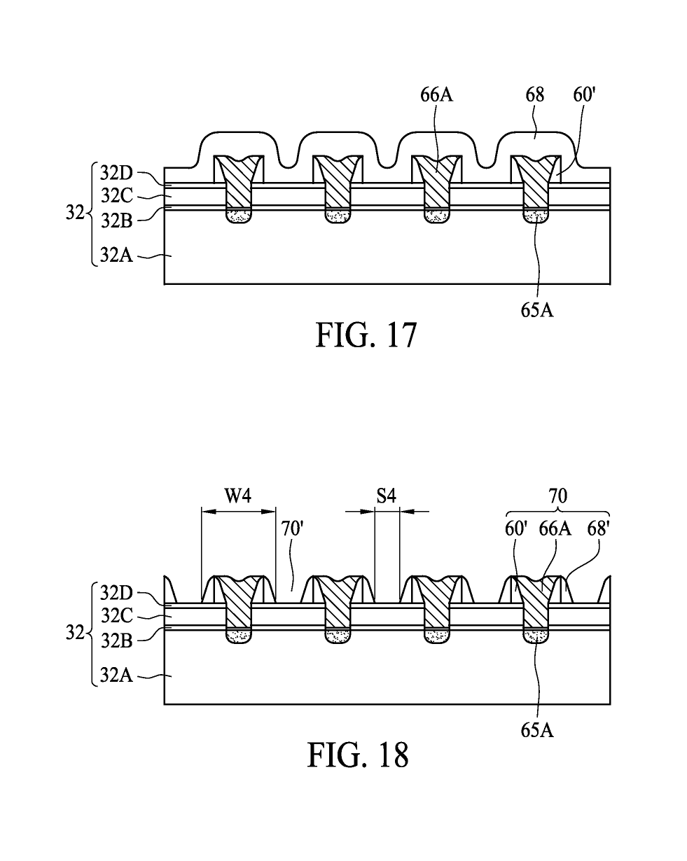

Referring to FIG. 17, a wet etching process is performed to completely remove the dielectric blocks 54′ to expose sidewalls of the spacers 60′, and a deposition process is then performed to form a dielectric layer 68 made of silicon oxide covering the substrate 32, the spacers 60′ and the isolation dielectric layer 66A. Subsequently, an anisotropic dry etching process is performed to remove a portion of the dielectric layer 68 to form a plurality of spacers 68′ on the sidewall of the spacers 60′, as shown in FIG. 18. In particular, the spacers 60′, the spacers 68′ and the isolation dielectric layer 66A form an etching mask 70 having a plurality of openings 70′, and the width (W4) of the etching mask 70 between the openings 70′ is three times larger than the width (S4) of the openings 72. The openings 70′ of the etching mask 70 are formed between the openings 62′ of the etching mask 62.

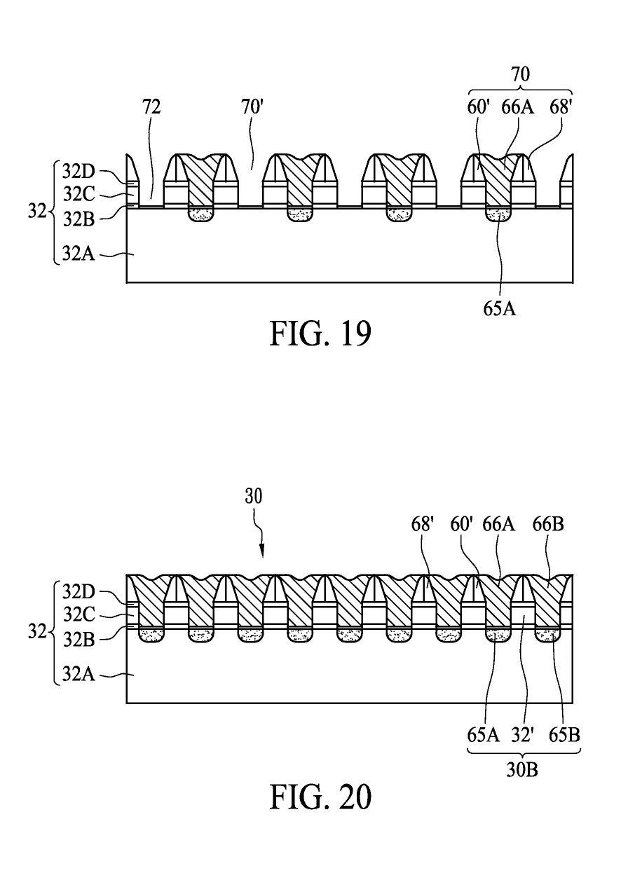

Referring to FIG. 19, an anisotropic dry etching process is performed to remove a portion of the substrate 32 not covered by the etching mask 70 to form a plurality of depressions 72 in the substrate 32. The anisotropic dry etching removes a portion of the substrate 32 under the openings 70′ down to the interior of the dielectric structure 32B such that the bottom of the depressions 72 is formed inside the dielectric structure 32B. Subsequently, an implanting process is performed to form a plurality of doped regions 65B in the silicon substrate 32A, and a high-density plasma chemical vapor phase deposition process and an etching process are performed to form an isolation dielectric layer 66B filling the depressions 72 to complete the flash memory structure 30, as shown in FIG. 20. In particular, the doped regions 65A and the doped regions 65B together with the polysilicon block 32′ form the memory cell structure 30B.

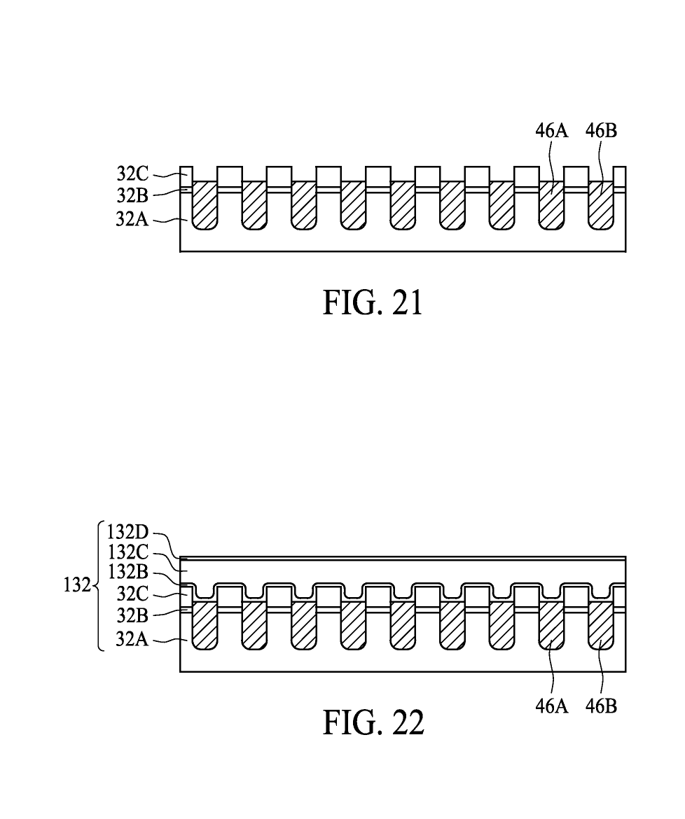

FIG. 21 to FIG. 23 illustrate a method for preparing a flash memory structure 30′ according to another embodiment of the present invention, which is used to prepare a floating gate flash memory device. Compared with the processes shown in FIG. 2 to FIG. 20 for preparing the SONOS-type flash memory device, the method for preparing the floating gate flash memory first performs the processes shown in FIG. 2 to FIG. 11, removes the silicon oxide layer 32D on the polysilicon layer 32C by a wet etching process, and removes a portion of the isolation dielectric layer 46A and the isolation dielectric layer 46B, as shown in FIG. 21, which is a cross-sectional view along the word line. In particular, the dielectric structure 32B serves as a tunneling oxide layer, while the polysilicon layer 32C serves as a floating gate.

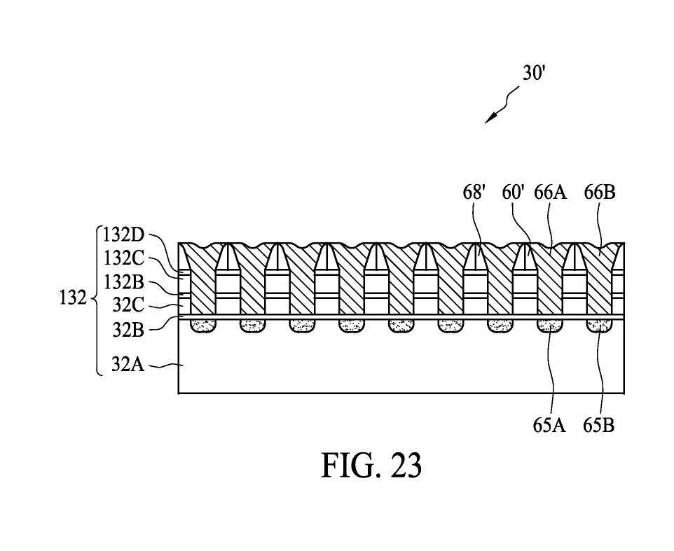

FIG. 22 is a cross-sectional view along the word line. A dielectric structure 132B, a polysilicon layer 132C and a silicon oxide layer 132D are formed by the deposition process to form a substrate 132. Subsequently, the processes shown in FIG. 12 to FIG. 20 are performed to complete the flash memory structure 30′, as shown in FIG. 23, which is a cross-sectional view along the bit line.

In summary, the present application divides the shallow trench isolation structure (the memory cell structure is the same) into two groups, uses the etching mask including the spacer to pattern the two shallow trench isolation groups, and performs two etching processes to form the complete shallow trench isolation structure. In particular, the present application uses the spacers to shrink the opening formed by the photolithographic process so as to fabricate a shallow trench isolation structure having a width smaller than the critical dimension of the photolithographic process to increase the storage density of the flash memory device.

The above-described embodiments of the present invention are intended to be illustrative only. Numerous alternative embodiments may be devised by those skilled in the art without departing from the scope of the following claims.

What is claimed is:

1. A method for preparing a flash memory structure, comprising the steps of:
forming a plurality of dielectric blocks having block sidewalls on a substrate;
forming a plurality of first spacers on the block sidewalls of the dielectric blocks;
removing a portion of the substrate not covered by the dielectric blocks and the first spacers to form a plurality of trenches in the substrate;
performing a deposition process to form an isolation dielectric layer filling the trenches;
removing the dielectric blocks to expose spacer sidewalls of the first spacers;
forming a plurality of second spacers on the spacer sidewalls of the first spacers; and
removing a portion of the substrate not covered by the first spacers, the second spacers and the isolation dielectric layer to form a plurality of second trenches in the substrate.

2. The method for preparing a flash memory structure of claim 1, wherein the substrate includes a silicon substrate and a dielectric structure positioned on the silicon substrate, and the first trenches have a bottom formed in the silicon substrate.

3. The method for preparing a flash memory structure of claim 1, wherein the step of forming a plurality of first spacers on the block sidewalls of the dielectric blocks includes:
forming a spacer dielectric layer covering the substrate and the dielectric blocks; and
performing an etching process to remove a portion of the spacer dielectric layer to form the first spacers.

4. The method for preparing a flash memory structure of claim 3, wherein the dielectric blocks include silicon nitride, and the spacer dielectric layer includes silicon oxide.

5. The method for preparing a flash memory structure of claim 1, wherein the dielectric blocks have an equal width and are formed on the substrate in an equally spaced manner.

6. The method for preparing a flash memory structure of claim 1, wherein the dielectric blocks have a width and are separated by a spacing equal to the width.

7. The method for preparing a flash memory structure of claim 1, wherein the first spacers and the dielectric blocks form a first etching mask having a width and a spacing smaller than the width.

8. The method for preparing a flash memory structure of claim 1, wherein the first spacers, the second spacers and the dielectric blocks form a second etching mask having a width and a spacing smaller than the width.

9. The method for preparing a flash memory structure of claim 1, wherein the first spacers and the dielectric blocks form a first etching mask having a plurality of first openings, and the first spacers, the second spacers and the dielectric blocks form a second etching mask having a plurality of second openings between the first openings.

10. The method for preparing a flash memory structure of claim 1, wherein the first trenches have a trench width, and the dielectric blocks have a block width larger than the trench width.

11. A method for preparing a flash memory structure, comprising the steps of:
forming a plurality of dielectric blocks having block sidewalls on a substrate;
forming a plurality of first spacers on the block sidewalls of the dielectric blocks;
removing a portion of the substrate not covered by the dielectric blocks and the first spacers to form a plurality of first depressions in the substrate;
performing a first implanting process to form a plurality of first doped regions in the substrate below the first depressions;
performing a deposition process to form an isolation dielectric layer filling the first depressions;
removing the dielectric blocks to expose spacer sidewalls of the first spacers;
forming a plurality of second spacers on the spacer sidewalls of the first spacers;
removing a portion of the substrate not covered by the first spacers, the second spacers and the isolation dielectric layer to form a plurality of second depressions in the substrate; and
performing a second implanting process to form a plurality of second doped regions in the substrate below the second depressions.

12. The method for preparing a flash memory structure of claim 11, wherein the substrate includes a silicon substrate and a dielectric structure positioned on the silicon substrate, and the first depressions have a bottom formed in the dielectric structure.

13. The method for preparing a flash memory structure of claim 11, wherein the step of forming a plurality of first spacers on the block sidewalls of the dielectric blocks includes:
forming a spacer dielectric layer covering the substrate and the dielectric blocks; and
performing an etching process to remove a portion of the spacer dielectric layer to form the first spacers.

14. The method for preparing a flash memory structure of claim 13, wherein the dielectric blocks include silicon nitride, and the spacer dielectric layer includes silicon oxide.

15. The method for preparing a flash memory structure of claim 11, wherein the dielectric blocks have an equal width and are formed on the substrate in an equally spaced manner.

16. The method for preparing a flash memory structure of claim 11, wherein the dielectric blocks have a width and are separated by a spacing equal to the width.

17. The method for preparing a flash memory structure of claim 11, wherein the first spacers and the dielectric blocks form a first etching mask having a width and a spacing smaller than the width.

18. The method for preparing a flash memory structure of claim 11, wherein the first spacers, the second spacers and the dielectric blocks form a second etching mask having a width and a spacing smaller than the width.

19. The method for preparing a flash memory structure of claim 11, wherein the first spacers and the dielectric blocks form a first etching mask having a plurality of first openings, and the first spacers, the second spacers and the dielectric blocks form a second etching mask having a plurality of second openings between the first openings.

20. The method for preparing a flash memory structure of claim 11, wherein the first trenches have a trench width, and the dielectric blocks have a block width larger than the trench width.
